(19) United States
(12) Patent Application Publication
(10) Pub. No.: US 2011/0095786 A1
(43) Pub. Date: Apr. 28, 2011

(54) PHASE COMPARATOR, PLL CIRCUIT, INFORMATION REPRODUCTION PROCESSING DEVICE, OPTICAL DISK PLAYBACK DEVICE AND MAGNETIC DISK PLAYBACK DEVICE

(76) Inventors: Akira Yamamoto, Osaka (JP); Yoshinori Shirakawa, Osaka (JP); Kouji Okamoto, Osaka (JP); Hiroki Mouri, Osaka (JP)

(21) Appl. No.: 12/515,337

(22) PCT Filed: Sep. 22, 2008
(86) PCT No.: PCT/JP2008/002610

§ 371 Date: May 18, 2009

(30) Foreign Application Priority Data
Nov. 26, 2007 (JP) 2007-304310

(51) Int. Cl. H03D 13/00

(52) U.S. Cl. 327/9

(57) ABSTRACT

In a phase comparator used for a sync clock extraction circuit for extracting a clock synchronizing with reproduction data, a zero cross detection section 701, receiving the reproduction data, outputs a rising cross detection signal, a falling cross detection signal and three phase error candidates that are three consecutive samples. Rising and falling reference value hold sections 703 and 704 respectively output rising and falling reference values. When receiving the rising or falling cross detection signal, a phase error calculation section 702 outputs a sample the difference of which from the rising or falling reference value is minimum in absolute value, out of the three samples including a zero cross sample, as a phase error. The phase error is held in the rising or falling reference value hold section 703 or 704 as the rising or falling reference value for the next phase error calculation.

### TECHNICAL FIELD

The present invention relates to a reproduction signal processing circuit for extracting data recorded in a recording medium such as an optical disk and a magnetic disk from the recording medium and also extracting a sync clock synchronizing with the data, and more particularly to a phase comparator used for extracting a sync clock.

### BACKGROUND ART

FIG. 3 shows an example of a reproduction signal processing circuit in a conventional general information reproduction processing device.

Referring to FIG. 3, the reference numeral 1 denotes a recording medium, 2 an optical pickup, 3 an analog front end, 4 an A/D converter, 5 a digital filter, 6 a maximum likelihood decoder, 7 a phase comparator, 8 and 11 loop filters, 9 a VCO, 10 a frequency comparator, 12 a digital signal processing circuit, and 13 a sync clock extraction circuit.

The operation of this circuit will be outlined. In reproduction of data written in a recording medium such as an optical disk, first, the recording medium 1 is irradiated with laser light, and light reflected therefrom is retrieved by the optical pickup 2. The optical pickup 2 converts the magnitude of the reflected light to an electric signal to generate an analog reproduction signal. The analog front end 3 subjects the analog reproduction signal from the optical pickup 2 to gain adjustment of the signal amplitude and DC offset adjustment and further, for the purpose of waveform equalization, to boosting of a high-frequency band and noise removal. The A/D converter 4 quantizes the analog reproduction signal subjected to the waveform equalization by the analog front end 3 to give digital data. In the subsequent steps, therefore, digital signal processing is to be performed. The reproduction data quantized by the A/D converter 4 is subjected to waveform correction by the digital filter 5 and to decoding by the maximum likelihood decoder 6 to give binary data.

The reproduction data quantized by the A/D converter 4 is also inputted into a sync clock extraction circuit 13 that is substantially composed of the phase comparator 7, the loop filter 8 for the phase comparator, the VCO 9, the frequency comparator 10 and the loop filter 11 for the frequency comparator. The frequency comparator 10 calculates the frequency error between the reproduction data and a clock outputted from the VCO 9, and the loop filter 11 filters the frequency error outputted from the frequency comparator 10. The VCO 9 changes the frequency according to the value of the frequency error smoothed by the loop filter 11. Likewise, the phase comparator 7 calculates the phase error between the reproduction data and the clock outputted from the VCO 9, and the loop filter 8 filters the phase error outputted from the phase comparator 7. The VCO 9 changes the frequency according to the value of the phase error smoothed by the loop filter 8. With this feedback loop, control is made so that the frequency error and the phase error become null.

As the operation of the sync clock extraction circuit 13, generally, first the frequency error correction and then the phase error correction are performed. The signal outputted from the VCO 9 is also supplied to the digital signal processing circuit 12 including the A/D converter 4. Once the frequency control and the phase control become their steady states, the output clock of the VCO 9 is in synchronization with the reproduction data.

FIG. 12 shows an example of the configuration of the conventional phase comparator that poses a problem to be solved. The phase comparator 7 is substantially composed of a zero cross detection section 70 and a phase error calculation section 71. This configuration of the conventional phase comparator is described in Patent Documents 1 and 2, for example. The operation of the phase error calculation section 71 will be outlined as follows.

The zero cross detection section 70 detects the time point at which the quantized reproduction data PBD crosses the zero level. At this time, the phase error calculation section 71 calculates zero cross sample data as phase error data. FIG. 13 shows how the operation of the phase error calculation section 71 described with reference to FIG. 12 is performed.
Patent Document 1: Japanese Patent Gazette No. 3889027
Patent Document 1: Japanese Laid-Open Patent Publication No. 2002-358734

### DISCLOSURE OF THE INVENTION

### Problems to be Solved by the Invention

However, the phase comparator 7 having the conventional phase error calculation section 71 described above has the following drawback. FIG. 13 shows how a phase error is calculated when a 3T+3T (T is a channel period) reproduction waveform is sampled with a 1.05T-period clock. The conventional phase error calculation section 71 calculates a phase error using data at the time when the reproduction signal crosses zero. Hence, the linear range of the phase comparator 7 is −π to +π as shown in FIG. 14, and the sign of the output value is reversed once the value falls out of the linear range. For this reason, when the frequency deviation is great and when the latency of the phase control loop is great, a problem occurs that the synchronizing characteristic (capture range) of the clock generation circuit widely deteriorates.

### Means for Solving the Problems

To solve the problem described above, an object of the present invention is to widen the linear range (capture range) within which the phase comparator calculates a phase error properly without occurrence of reversal of the sign of the phase error.

To attain the above object, according to the present invention, the phase comparator is configured to have three consecutive data units, among a plurality of data units inputted consecutively, as candidates for phase error calculation and select one of the three candidates properly.

Specifically, the phase comparator of the present invention receives a plurality of consecutive samples, determines three samples including a zero cross sample crossing a zero value and two samples preceding and following the zero cross sample, among the plurality of samples, as phase error candidates, and selects one sample out of the three phase error candidates and outputting the selected sample as a phase error.

In the phase comparator described above, in selecting one sample out of the three phase error candidates, a sample closest to a predetermined reference value may be selected.

The phase comparator described above may include a reference value hold section for holding a phase error as the predetermined reference value.

In the phase comparator described above, as the predetermined reference value, a rising reference value may be used when the three phase error candidates include a zero cross sample crossing the zero value during rising, and a falling reference value may be used when the three phase error candidates include a zero cross sample crossing the zero value during falling.

In the phase comparator described above, the reference value hold section may hold a rising phase error in the case of crossing during rising, or a falling phase error in the case of crossing during falling, as a new reference value.

Alternatively, the phase comparator of the present invention receives a plurality of consecutive samples, determines three samples including a zero cross sample crossing a zero value and two samples preceding and following the zero cross sample, among the plurality of samples, as phase error candidates, and switches between selecting and outputting one sample out of the three phase error candidates as a phase error and outputting the zero cross sample as a phase error.

In the phase comparator described above, the switching may be performed based on synchronization determination.

In the phase comparator described above, in the synchronization determination, whether synchronous or asynchronous may be determined based on whether or not the proportion in which the value of the zero cross sample exists within a predetermined range falls within a predetermined allowance.

In the phase comparator described above, in the synchronization determination, whether synchronous or asynchronous may be determined based on whether or not jitter falls within a predetermined range.

The PLL circuit of the present invention includes the phase comparator described above.

The information reproduction processing circuit of the present invention includes the PLL circuit described above.

The optical disk playback device of the present invention includes the information reproduction processing circuit described above.

The magnetic disk playback device of the present invention includes the information reproduction processing circuit described above.

As described above, according to the present invention, three reproduction data units including zero cross sample data (data sampled near the point at which the waveform crosses the zero point) and two reproduction data units preceding and following the zero cross sample data are determined as phase error candidates, and one of the candidates is selected properly as the phase error. For example, among three reproduction data units including the zero cross sample data during rising as the center, a reproduction data value closest to the phase error during rising calculated last time is determined as the phase error. Likewise, among three reproduction data units including the zero cross sample data during falling as the center, a reproduction data value closest to the phase error during falling calculated last time is determined as the phase error. With this, the capture range of the phase comparator can be widened, and hence by applying this phase comparator to a reproduction signal processing circuit for extracting data recorded on an optical disk and the like and a sync clock synchronizing with this data, for example, swift clock synchronization can be attained.

### Effect of the Invention

As described above, according to the phase comparator of the present invention, three reproduction data units including a zero cross sample of data and two reproduction data units preceding and following the zero cross sample are determined as phase error candidates, and one of the candidates is selected properly as the phase error. Hence, a phase comparator capable of widening its capture range can be provided.

### BRIEF DESCRIPTION OF THE DRAWINGS

FIG. 1 is a view showing a configuration of a phase comparator of Embodiment 1 of the present invention.

FIG. 2 is a view showing a configuration of a phase comparator of Embodiment 2 of the present invention.

FIG. 3 is a view showing an example of a reproduction signal processing circuit for an optical disk.

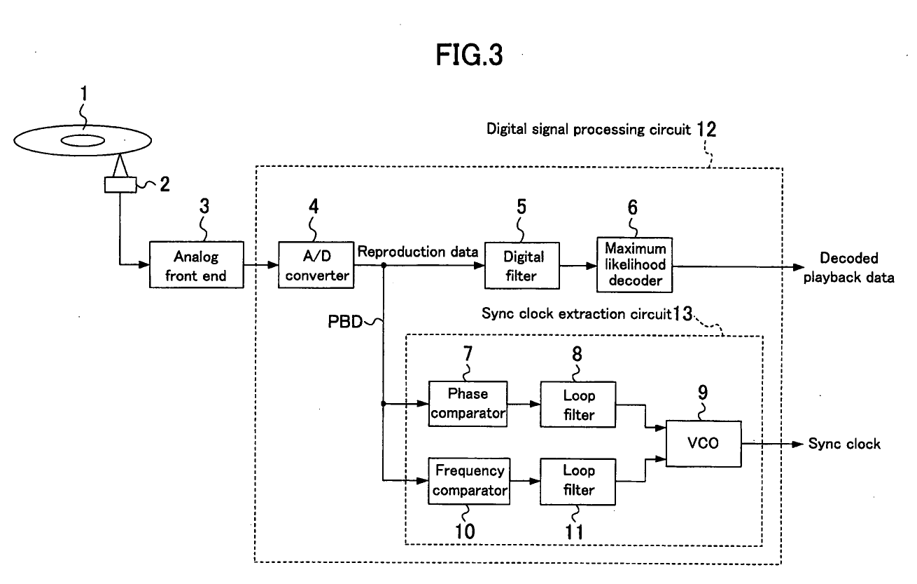

FIG. 4 is a view showing an example of the configuration of a zero cross detection section of the phase comparator of Embodiment 1.

FIG. 5 is a view showing an example of the configuration of a phase error calculation section of the phase comparator of Embodiment 1.

FIG. 6 is a view showing an example of the configuration of a rising reference value hold section of the phase comparator of Embodiment 1.

FIG. 7 is a view illustrating how the phase error calculation section of the phase comparator of Embodiment 1 calculates a phase error.

FIG. 8 is a view illustrating a capture range of the phase comparator of Embodiment 1.

FIG. 9 is a view showing an example of the configuration of a sync determination section of the phase comparator of Embodiment 2.

FIG. 10 is a view showing an example of the configuration of a phase error calculation section of the phase comparator of Embodiment 2.

FIG. 11 is a view illustrating how the phase error calculation section of the phase comparator of Embodiment 2 calculates a phase error before and after synchronization determination.

FIG. 12 is a view showing an example of the configuration of a conventional phase comparator.

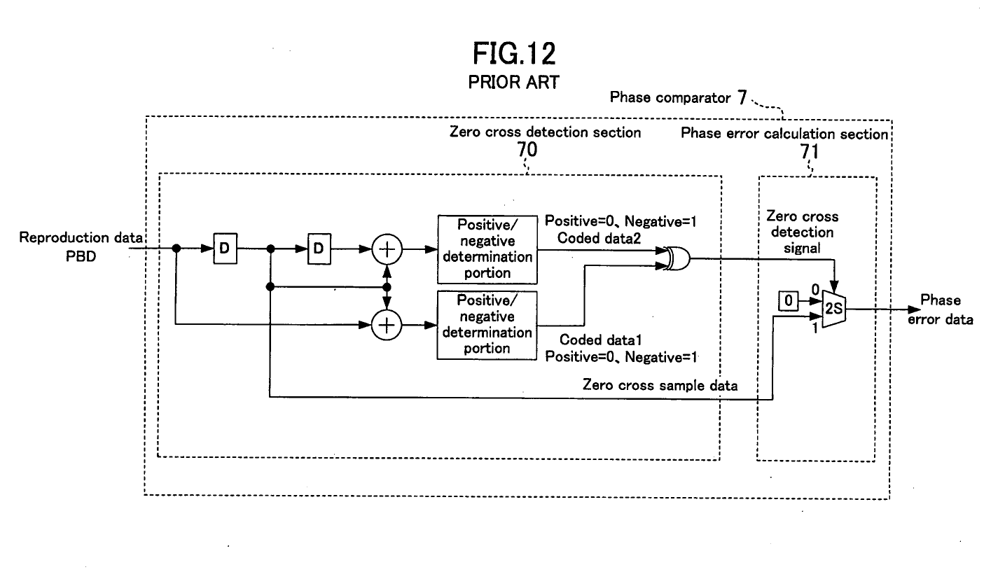

FIG. 13 is a view illustrating how the conventional phase comparator calculates a phase error.

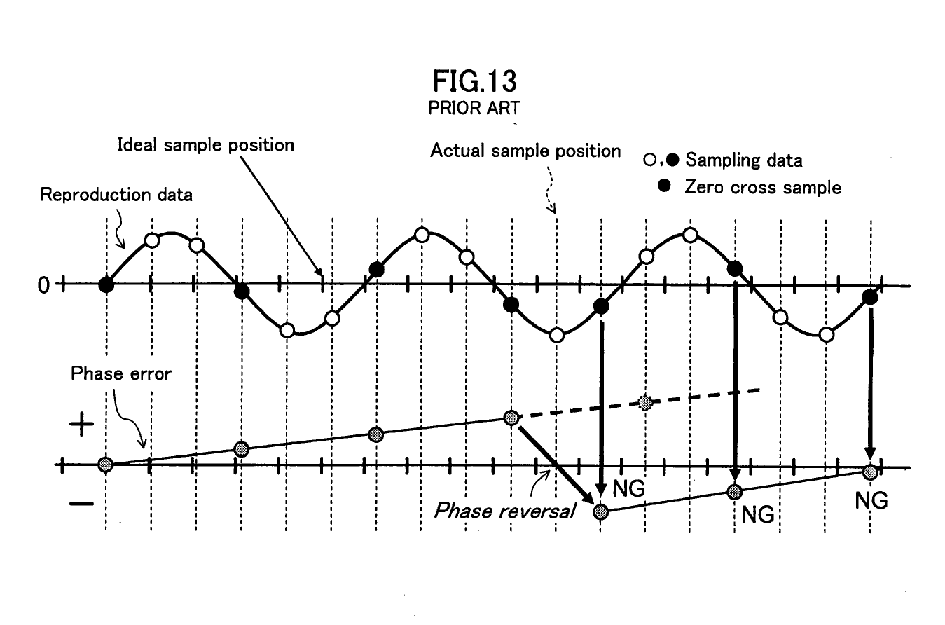

FIG. 14 is a view illustrating a capture range of the conventional phase comparator.

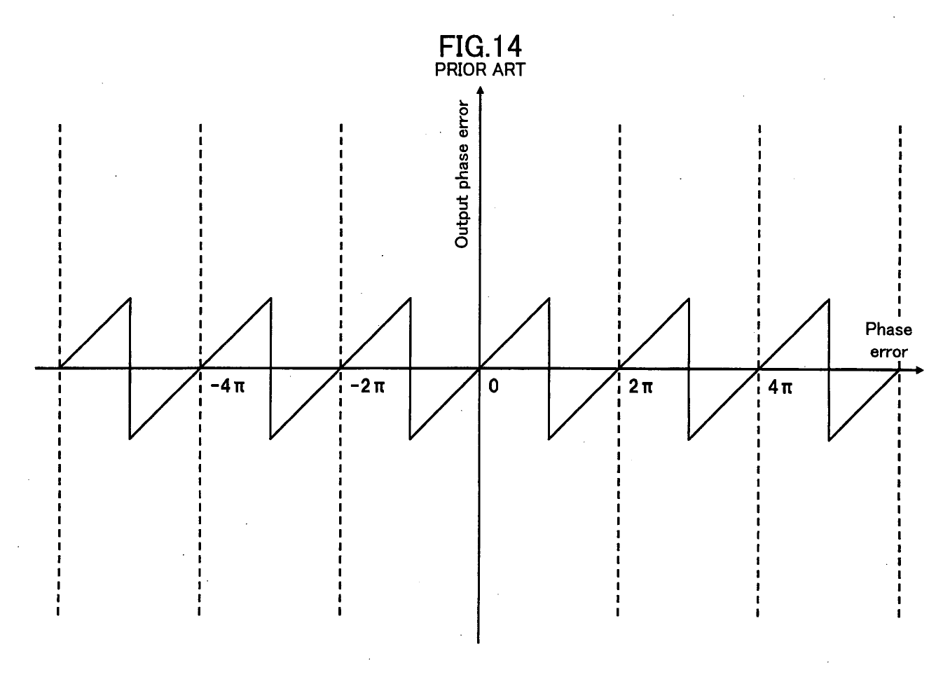

### DESCRIPTION OF REFERENCE NUMERALS

1 Recording medium

2 Optical pickup

3 Analog front end

4 A/D converter

5 Digital filter

6 Maximum likelihood decoder

7 Phase comparator

8, 11 Loop filter

9 VCO

10 Frequency comparator

12 Digital signal processing circuit

13 Sync clock extraction circuit

701 Zero cross detection section

702 Phase error calculation section

703 Rising reference value hold section

704 Falling reference value hold section

705 Sync determination section

706 Phase error calculation section

707, 708 Flipflop

709, 710 Adder

711, 712 Positive/negative determination portion

713, 714 1-input NOT AND circuit

715 OR circuit

716, 717 Selector

718, 719, 720 Subtractor

721, 722, 723 Absolute value conversion portion

724 Minimum determination portion

725 to 728, 735 Selector

729 Flipflop

730 Zero cross count portion

731 Zero cross count determination portion

732 Zero cross data determination portion

733 Zero cross data count portion

734 Zero cross data count determination portion

### BEST MODE FOR CARRYING OUT THE INVENTION

Hereinafter, embodiments of the present invention will be described based on the drawings.

### Embodiment 1

Embodiment 1 of the present invention will be described with reference the relevant drawings.

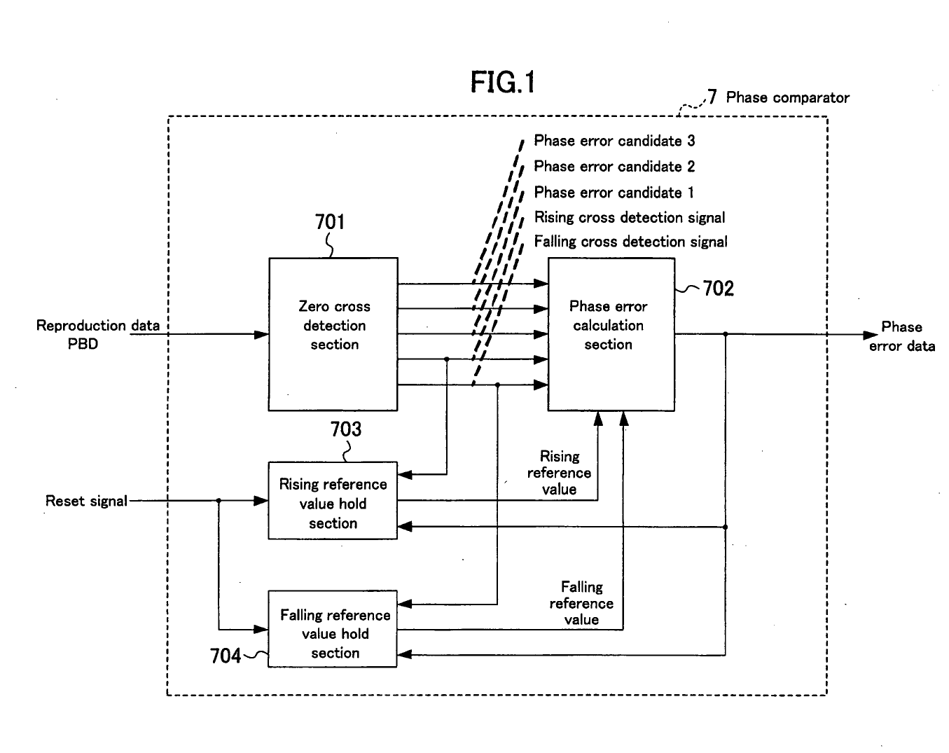

FIG. 1 shows a configuration of a phase comparator of Embodiment 1 of the present invention. Referring to FIG. 1, the reference numeral 7 denotes a phase comparator that calculates a phase error from reproduction data and outputs the calculated phase error. The reference numeral 701 denotes a zero cross detection section that detects reproduction data crossing the zero level during rising or falling and also determines a zero cross sample of data at this time and two samples preceding and following the zero cross sample, i.e., a total of three reproduction data units, as phase error candidates. The reference numeral 702 denotes a phase error calculation section that calculates a candidate closest to a rising reference value during rising, or a candidate closest to a falling reference value during falling, as the phase error. The reference numeral 703 denotes a rising reference value hold section that updates the phase error during rising as a new rising reference value, and 704 a falling reference value hold section that updates the phase error during falling as a new falling reference value.

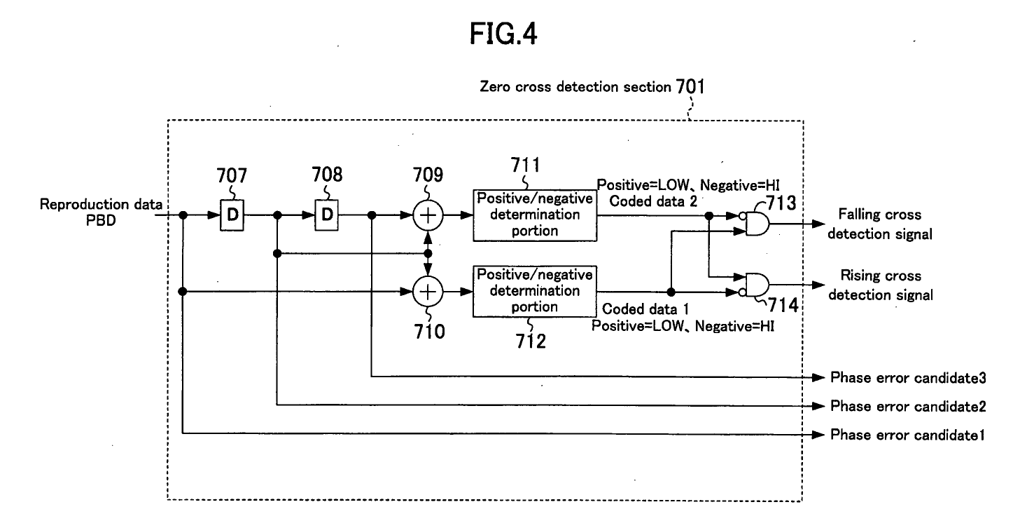

FIG. 4 shows a configuration of the zero cross detection section 701 in FIG. 1. Referring to FIG. 4, the reference numerals 707 and 708 denote flipflops, 709 and 710 adders, 711 and 712 positive/negative determination portions that determine whether the added result is positive or negative, and 713 and 714 AND circuits whose one input is NOT.

Hereinafter, the zero cross detection operation will be described with reference to FIG. 4. First, quantized reproduction data PBD is inputted into the zero cross detection section 701. The reproduction data PBD is held in the flipflops 707 and 708 consecutively. The adder 709 then adds 1-clock preceding reproduction data held in the flipflop 707 to 2-clock preceding reproduction data held in the flipflop 708. The adder 710 adds the current reproduction data to the 1-clock preceding reproduction data held in the flipflop 707. The positive/negative determination portion 711 determines whether the added result from the adder 709 is positive or negative, while the positive/negative determination portion 712 determines whether the added result from the adder 710 is positive or negative, and they output LOW if positive or HIGH if negative. The AND circuits 713 and 714 determine rising zero cross or falling zero cross from the results of the negative/positive determination portions 711 and 712. If the negative/positive determination portions 711 and 712 output LOW and HIGH, respectively, falling zero cross is detected and thus a falling cross detection signal HIGH is outputted. If the negative/positive determination portions 711 and 712 output HIGH and LOW, respectively, rising zero cross is detected and thus a rising cross detection signal HIGH is outputted. Also, the zero cross detection section 701 outputs the reproduction data as a phase error candidate 1, the value held in the flipflop 707 as a phase error candidate 2 and the value held in the flipflop 708 as a phase error candidate 3.

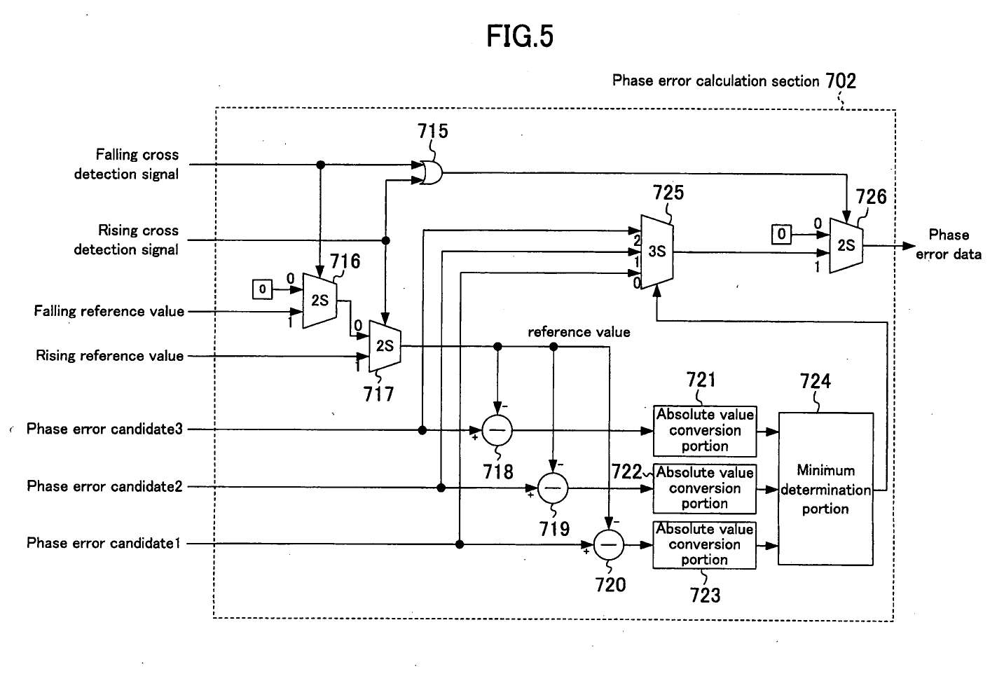

FIG. 5 shows an example of the configuration of the phase error calculation section 702 in FIG. 1. The reference numeral 715 denotes an OR circuit, 716 and 717 selectors, 718, 719 and 720 subtractors, 721, 722 and 723 absolute value conversion portions, 724 a minimum value determination portion, and 725 and 726 selectors.

Hereinafter, the phase error calculation operation will be described with reference to FIG. 5. The phase error calculation section 702 receives the rising cross detection signal, the falling cross detection signal, the phase error candidates 1, 2 and 3, the rising reference value and the falling reference value. The OR circuit 715 determines that zero crossing has occurred. The selectors 716 and 717 select the rising reference value when the rising cross detection signal is HIGH, or the falling reference value when the falling cross detection signal is HIGH, as the reference value for phase error calculation. The subtractors 718, 719 and 720 respectively subtract the reference value from the phase error candidate 3, the phase error candidate 2 and the phase error candidate 1. The absolute value conversion portions 721, 722 and 723 respectively convert the subtraction results from the subtractors 718, 719 and 720 to their absolute values, and the minimum value determination portion 724 determines a phase error candidate having the minimum absolute value. The selector 725 selects the phase error candidate determined by the minimum determination portion 724, and the selector 726 outputs the selected phase error candidate as the phase error data only in the case of zero crossing. In a case other than zero crossing, “0” is outputted as the phase error data.

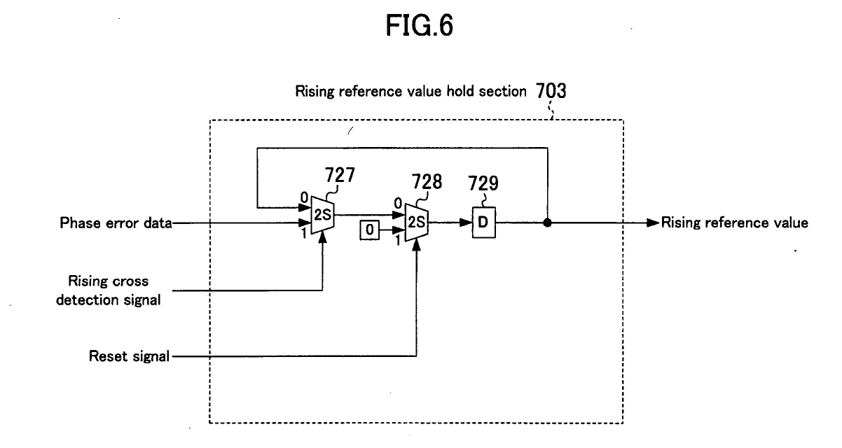

FIG. 6 shows an example of the configuration of the rising reference value hold section 703 in FIG. 1. Referring to FIG. 6, the reference numerals 727 and 728 denote selectors, and 729 a flipflop.

Hereinafter, the rising reference value hold operation will be described with reference to FIG. 6. The rising reference value hold section 703 receives the phase error data, the rising cross detection signal and an external reset signal. When the reset signal is HIGH, “0” is inputted into the flipflop 729 via the selector 728 and held therein. When the reset signal is LOW, the phase error data is inputted into and held in the flipflop 729 via the selector 728 only if the rising cross detection signal is HIGH. The value held in the flipflop 729 is outputted as the rising reference value.

The falling reference value hold section 704 in FIG. 1 is the same in configuration as the rising reference value hold section 703 except that the rising cross detection signal and the rising reference value in FIG. 6 are changed to the falling cross detection signal and the falling reference value, respectively.

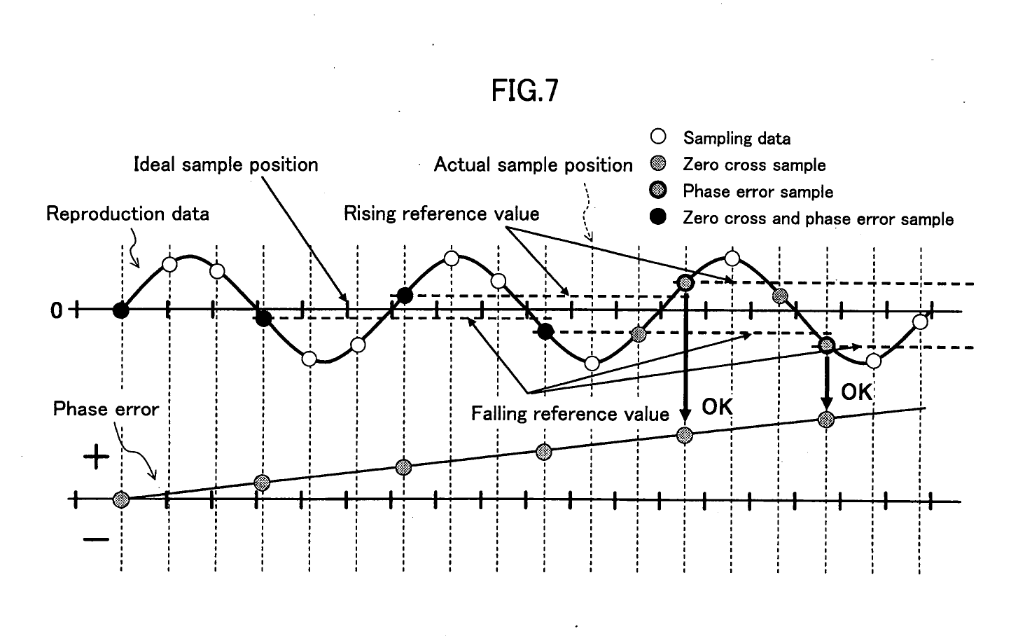

How the phase comparator 7 of this embodiment performs the phase error calculation will be described with reference to FIG. 7. FIG. 7 shows how the phase error calculation is performed when a 3T+3T (T is a channel period) reproduction waveform is sampled with a 1.05T-period clock. Sample data includes in particular a zero cross sample, a phase error sample and a zero cross and phase error sample. Out of three samples including a zero cross sample and its preceding and following samples, a sample closest to the reference value is considered as the phase error, and this phase error is used as the reference value in the next phase error calculation. Note that the reference value adopted is different between during rising and during falling.

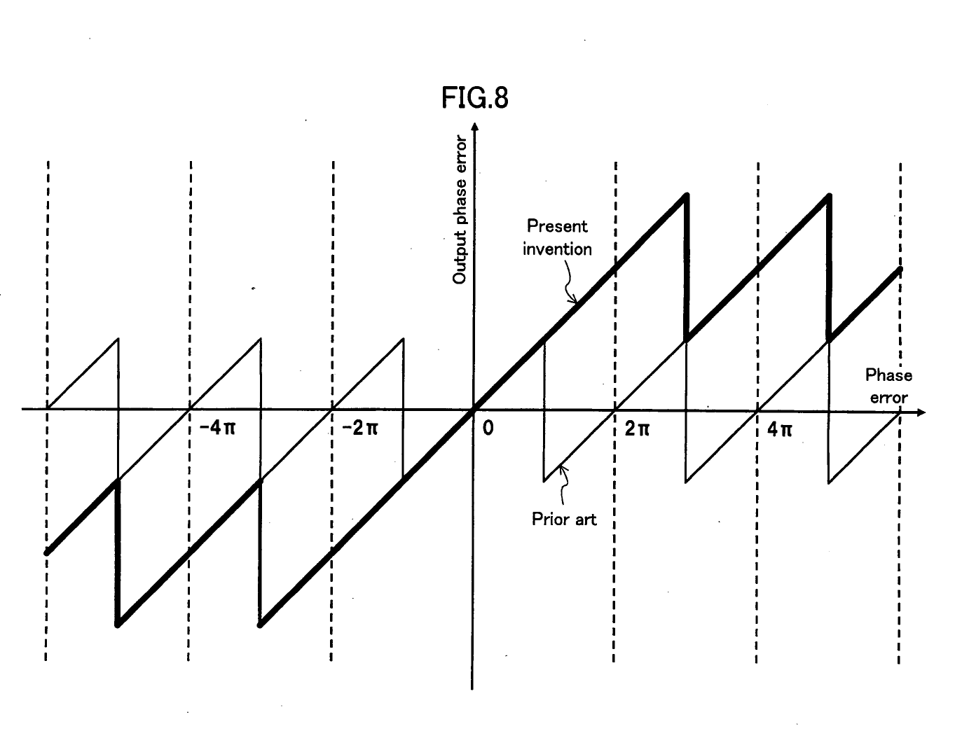

As described above, three samples including a zero cross sample and its preceding and following samples are used as phase error candidates. One phase error is selected from the three phase error candidates using the phase error calculated one process step earlier. In this way, as shown in FIG. 8, the capture range of the phase comparator 7 can be widened to −3π to +3π.

### Embodiment 2

A phase comparator of Embodiment 2 of the present invention will be described.

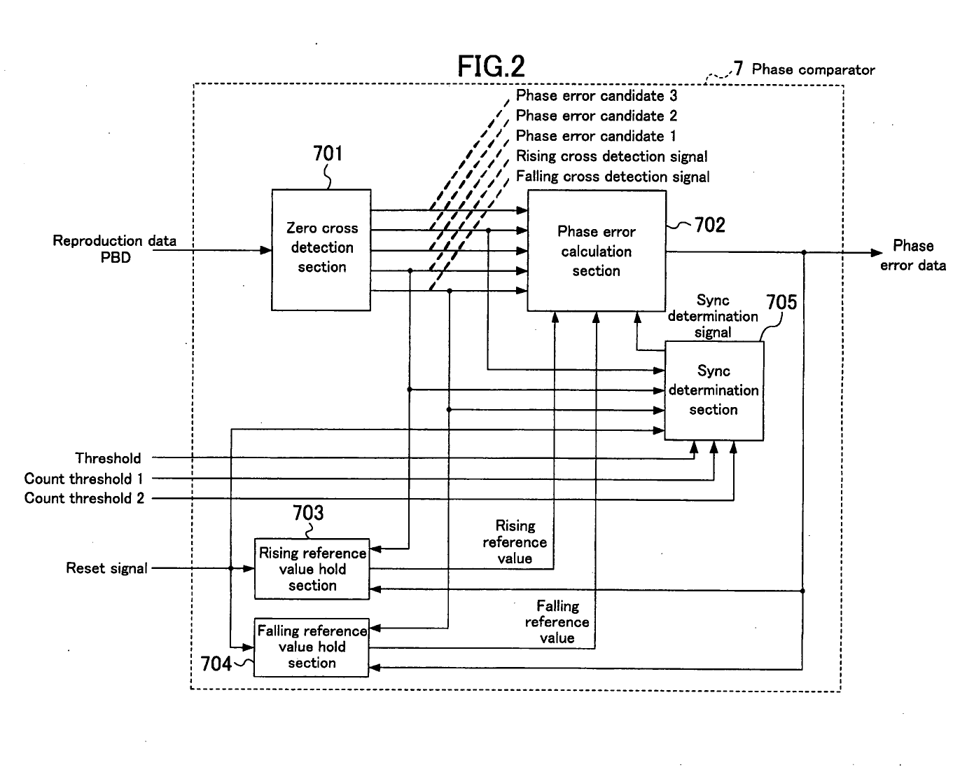

Referring to FIG. 2, the reference numeral 701 denotes a zero cross detection section, 703 a rising reference value hold section, 704 a falling reference value hold section, 705 a sync determination section, and 706 a phase error calculation section. The zero cross detection section 701, the rising reference value hold section 703 and the falling reference value hold section 704 are the same as those in Embodiment 1 described above, and hence description thereof is omitted in this embodiment.

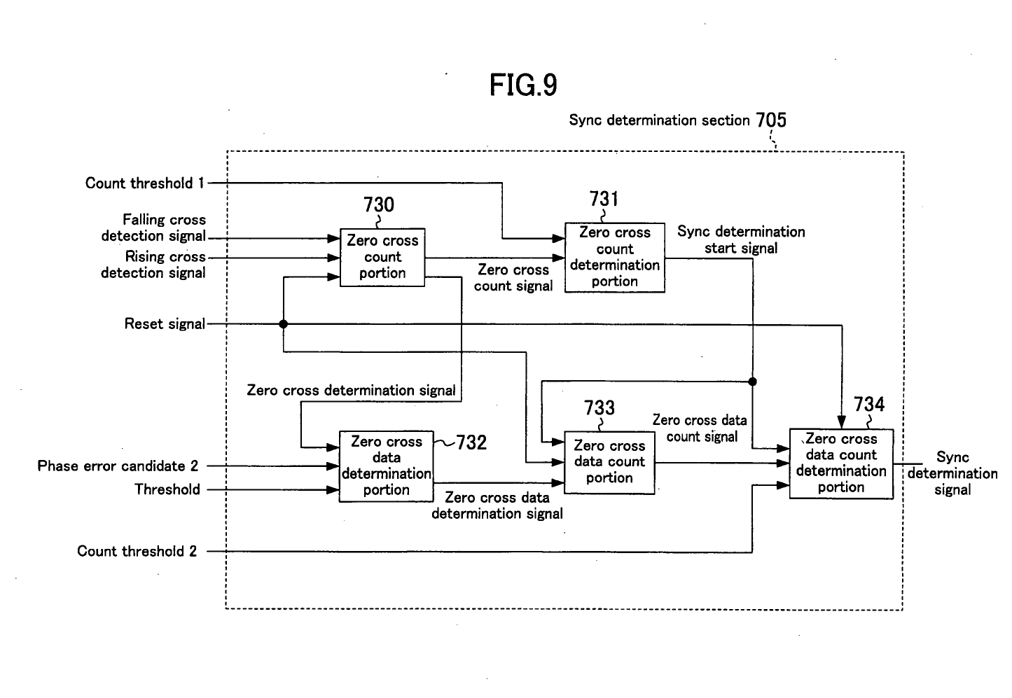

FIG. 9 shows an internal configuration of the sync determination section 705. Referring to FIG. 9, the reference numeral 730 denotes a zero cross count portion, 731 a zero cross count determination portion, 732 a zero cross data determination portion, 733 a zero cross data count portion, and 734 a zero cross data count determination portion.

The sync determination section 705 receives the rising cross detection signal, the falling cross detection signal, the phase error candidate 2, an external reset signal, a count threshold 1, a count threshold 2 and a threshold. The zero cross count portion 730 determines that zero crossing has occurred and turns a zero cross determination signal to HIGH, and also counts the number of times by which the zero cross determination signal goes HIGH and outputs the count number as a zero cross count signal. The zero cross count determination portion 731 determines whether or not the zero cross count signal is equal to the count threshold 1 and, if equal, turns a sync determination start signal to HIGH. The zero cross data determination portion 732 determines whether or not the phase error candidate 2 as the zero cross data is equal to or less than the threshold and, if so, turns a zero cross data determination signal to HIGH. The zero cross data count portion 733 counts the number of times by which the zero cross determination signal goes HIGH and also the zero cross data determination signal goes HIGH and outputs the count number as a zero cross data count signal. The zero cross data count determination portion 734 turns a sync determination signal to HIGH when the zero cross data count signal is equal to or more than the count threshold 2 at the timing at which the sync determination start signal is HIGH.

The sync determination section 705 having the configuration described above determines that synchronization is secured if the proportion in which the value of the zero cross data exists within a predetermined range (i.e., the variation of the zero cross data) falls within an allowance. Note that a variety of other configurations can be adopted for the synchronization determination. For example, a method using jitter and the like may be adopted.

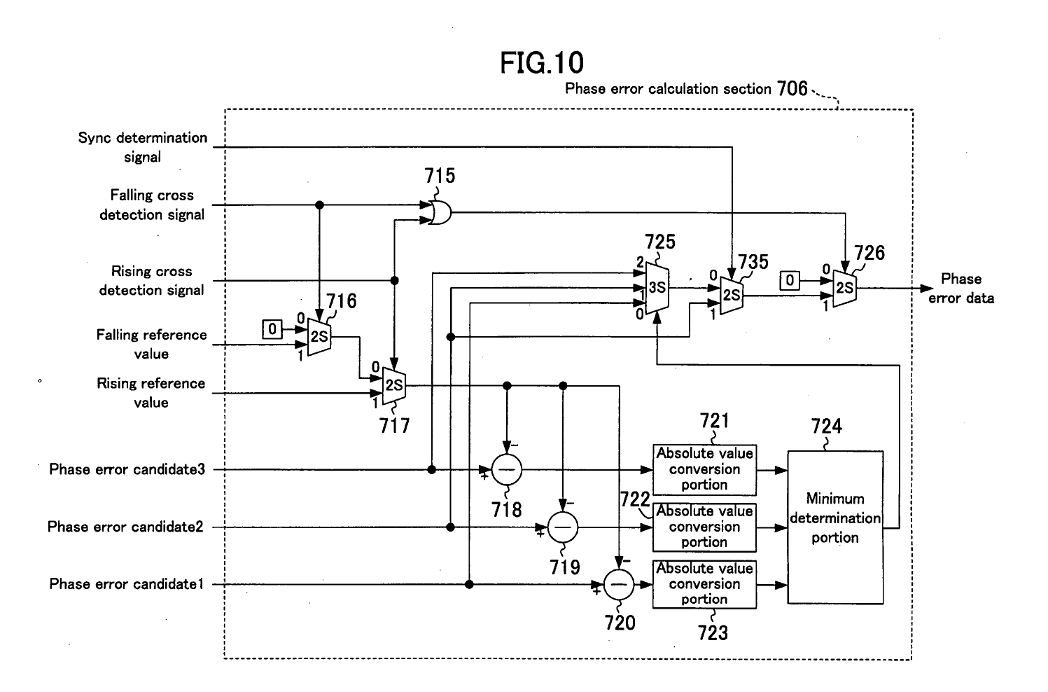

FIG. 10 shows an internal configuration of the phase error calculation section 706. The phase error calculation section 706 is the same as the phase error calculation section 702 except that the sync determination signal is inputted and that a selector 735 is added. The selector 735 selects the phase error candidate 2 as the phase error when the sync determination signal is HIGH.

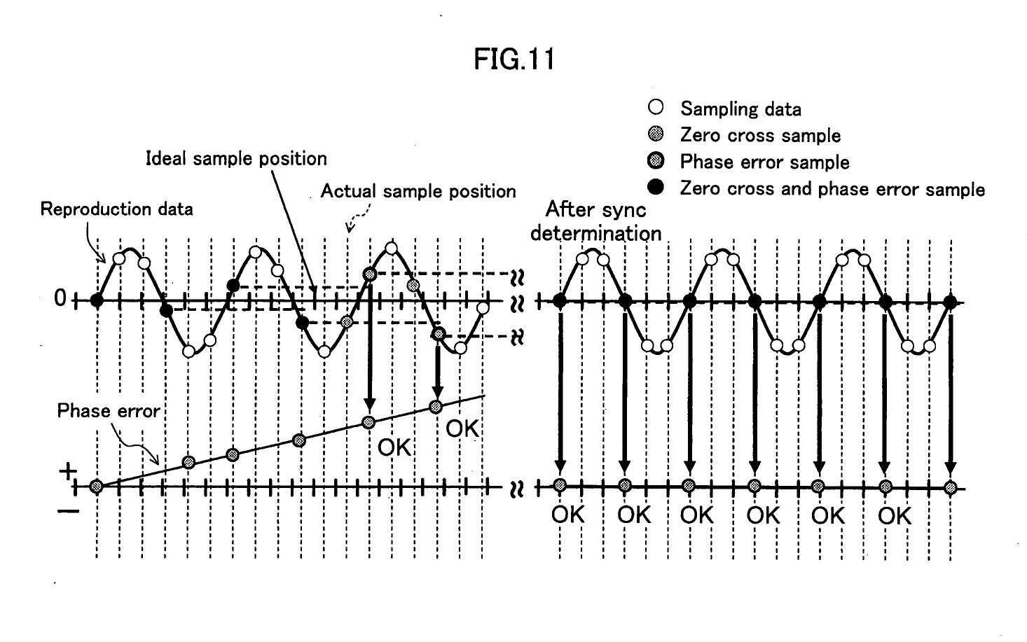

The phase error calculation operation of the phase comparator of this embodiment will be described with reference to FIG. 11. FIG. 11 shows how the phase error calculation is performed when a 3T+3T (T is a channel period) reproduction waveform is sampled with a 1.05T-period clock. The sample data includes in particular a zero cross sample, a phase error sample and a zero cross and phase error sample. Out of three samples including a zero cross sample and its preceding and following samples, a sample closest to the reference value is considered as the phase error, and this phase error is used as the reference value in the next phase error calculation. After the synchronization, the zero cross sample of data is used as the phase error.

As described above, three samples including a zero cross sample and its preceding and following samples are used as phase error candidates. One phase error is selected from the three phase error candidates using a phase error used one process step earlier as the reference value. After the synchronization determination, the zero cross sample is used as the phase error. In this way, the capture range of the phase comparator 7 can be widened to −3π to +3π while the feedback control is suppressed from diverging.

### INDUSTRIAL APPLICABILITY

As described above, according to the phase comparator of the present invention, the capture range within which the phase error can be calculated properly with no phase reversal occurring can be widened. Hence, by applying the phase comparator to a reproduction signal processing circuit for extracting data recorded on an optical disk and the like and a sync clock synchronizing with this data, swift clock synchronization can be attained.

1. A phase comparator characterized in
receiving a plurality of consecutive samples of data,
determining three samples including a zero cross sample crossing a zero value and two samples preceding and following the zero cross sample, among the plurality of samples, as phase error candidates, and
selecting one sample out of the three phase error candidates and outputting the selected sample as a phase error.

2. The phase comparator of claim 1, wherein in selecting one sample out of the three phase error candidates, a sample closest to a predetermined reference value is selected.

3. The phase comparator of claim 2, comprising a reference value hold section for holding a phase error as the predetermined reference value.

4. The phase comparator of claim 2, wherein as the predetermined reference value,
a rising reference value is used when the three phase error candidates include a zero cross sample crossing the zero value during rising, and
a falling reference value is used when the three phase error candidates include a zero cross sample crossing the zero value during falling.

5. The phase comparator of claim 3, wherein the reference value hold section holds a rising phase error in the case of crossing during rising, or a falling phase error in the case of crossing during falling, as a new reference value.

6. A phase comparator characterized in
receiving a plurality of consecutive samples of data,
determining three samples including a zero cross sample crossing a zero value and two samples preceding and following the zero cross sample, among the plurality of samples, as phase error candidates, and
switching between selecting and outputting one sample out of the three phase error candidates as a phase error and outputting the zero cross sample as a phase error.

7. The phase comparator of claim 6, wherein the switching is performed based on synchronization determination.

8. The phase comparator of claim 7, wherein in the synchronization determination, whether synchronous or asynchronous is determined based on whether or not the proportion in which the values of the zero cross samples exist within a predetermined range falls within a predetermined allowance.

9. The phase comparator of claim 7, wherein in the synchronization determination, whether synchronous or asynchronous is determined based on whether or not jitter falls within a predetermined range.

10. A PLL circuit comprising the phase comparator of claim 1.

11. An information reproduction processing circuit comprising the PLL circuit of claim 10.

12. An optical disk playback device comprising the information reproduction processing circuit of claim 11.

13. A magnetic disk playback device comprising the information reproduction processing circuit of claim 11.
